(19) United States
(12) Patent Application Publication
(10) Pub. No.: US 2012/0164480 A1
(43) Pub. Date: Jun. 28, 2012

(54) COATED ARTICLE AND METHOD FOR MAKING THE SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); XIAO-QIANG CHEN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/213,403

(22) Filed: Aug. 19, 2011

(30) Foreign Application Priority Data
Dec. 28, 2010 (CN) 201010609026.8

(51) Int. Cl. B32B 15/01; C23C 14/34

(52) U.S. Cl. 428/652; 204/192.15

(57) ABSTRACT

A coated article includes a substrate and an anti-corrosion layer formed on the substrate. The substrate is made of aluminum or aluminum alloy. The anti-corrosion layer is an aluminum-copper alloy layer implanted with manganese ions. The coated article has good corrosion resistance.

### CROSS-REFERENCE TO RELATED APPLICATIONS

This application is one of the eleven related co-pending U.S. patent applications listed below. All listed applications have the same assignee. The disclosure of each of the listed applications is incorporated by reference into all the other listed applications.

| Attorney | | |
|---|---|---|
| Docket No. | Title | Inventors |
| US 34965 | COATED ARTICLE AND METHOD | HSIN-PEI |
| | FOR MAKING THE SAME | CHANG et al. |
| US 34966 | COATED ARTICLE AND METHOD | HSIN-PEI |
| | FOR MAKING THE SAME | CHANG et al. |
| US 34967 | COATED ARTICLE AND METHOD | HSIN-PEI |
| | FOR MAKING THE SAME | CHANG et al. |
| US 34969 | COATED ARTICLE AND METHOD | HSIN-PEI |
| | FOR MAKING THE SAME | CHANG et al. |
| US 36035 | COATED ARTICLE AND METHOD | HSIN-PEI |
| | FOR MAKING THE SAME | CHANG et al. |
| US 36036 | COATED ARTICLE AND METHOD | HSIN-PEI |
| | FOR MAKING THE SAME | CHANG et al. |
| US 36037 | COATED ARTICLE AND METHOD | HSIN-PEI |
| | FOR MAKING THE SAME | CHANG et al. |
| US 36038 | COATED ARTICLE AND METHOD | HSIN-PEI |
| | FOR MAKING THE SAME | CHANG et al. |
| US 36039 | COATED ARTICLE AND METHOD | HSIN-PEI |
| | FOR MAKING THE SAME | CHANG et al. |
| US 36040 | COATED ARTICLE AND METHOD | HSIN-PEI |
| | FOR MAKING THE SAME | CHANG et al. |
| US 36041 | COATED ARTICLE AND METHOD | HSIN-PEI |
| | FOR MAKING THE SAME | CHANG et al. |

### BACKGROUND

1. Technical Field

The present disclosure relates to coated articles and a method for making the coated articles.

2. Description of Related Art

Physical vapor deposition (PVD) is an environmentally friendly coating technology. Coating metal substrates using PVD is widely applied in various industrial fields.

The standard electrode potential of aluminum or aluminum alloy is very low. Thus, the aluminum or aluminum alloy substrates may often suffer galvanic corrosion. When the aluminum or aluminum alloy substrate is coated with a decorative layer such as a titanium nitride (TiN) or chromium nitride (CrN) layer using PVD, the potential difference between the decorative layer and the substrate is high and the decorative layer made by PVD will often have small openings such as pinholes and cracks, which can accelerate the galvanic corrosion of the substrate.

Therefore, there is room for improvement within the art.

### BRIEF DESCRIPTION OF THE FIGURE

Many aspects of the coated article and the method for making the coated article can be better understood with reference to the following drawings. The components in the drawings are not necessarily drawn to scale, the emphasis instead being placed upon clearly illustrating the principles of the coated article and the method. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary coated article;

FIG. 2 is a schematic view of a vacuum sputtering device for fabricating the coated article in FIG. 1.

### DETAILED DESCRIPTION

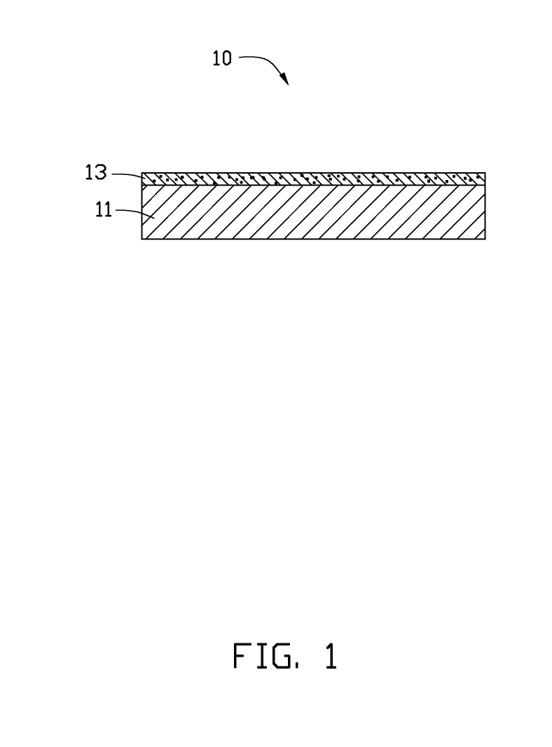

FIG. 1 shows a coated article 10 according to an exemplary embodiment. The coated article 10 includes a substrate 11, and an anti-corrosion layer 13 formed on the substrate 11. The anti-corrosion layer 13 is an aluminum-copper alloy layer implanted with manganese (Mn) ions. The weight percentage of the Mn in the anti-corrosion layer 13 is about 1% to about 30%.

The substrate 11 is made of aluminum or aluminum alloy.

The anti-corrosion layer 13 has a thickness of about 0.5 μm to about 6.0 μm. A vacuum sputtering process may be used to form the aluminum-copper alloy layer, and the Mn ions may be formed in the aluminum-copper alloy layer by ion implanting.

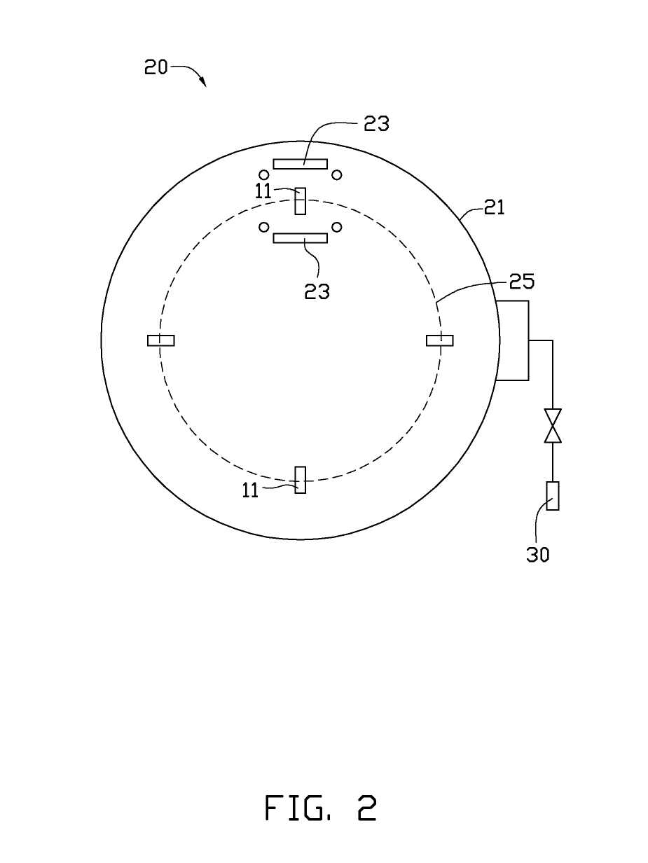

FIG. 2 shows a vacuum sputtering device 20, which includes a vacuum chamber 21 and a vacuum pump 30 connected to the vacuum chamber 21. The vacuum pump 30 is used for evacuating the vacuum chamber 21. The vacuum chamber 21 has aluminum-copper alloy targets 23 and a rotary rack (not shown) positioned therein. The rotary rack holding the substrate 11 revolves along a circular path 25, and the substrate 11 is also rotated about its own axis while being carried by the rotary rack. The weight percentage of copper in the aluminum-copper alloy targets 23 is about 0.5% to about 25%.

A method for making the coated article 10 may include the following steps:

The substrate 11 is pretreated. The pre-treating process may include the following steps:

The substrate 11 is ultrasonically cleaned with alcohol or acetone solution in an ultrasonic cleaner (not shown), to remove impurities such as grease or dirt from the substrate 11. Then, the substrate 11 is dried.

The substrate 11 is positioned in the rotary rack of the vacuum chamber 21 to be plasma cleaned. The vacuum chamber 21 is then evacuated to about 8.0×10⁻³ Pa. Argon gas (abbreviated as Ar, having a purity of about 99.999%) is used as the sputtering gas and is fed into the vacuum chamber 21 at a flow rate of about 300 standard-state cubic centimeters per minute (sccm) to about 500 sccm. A negative bias voltage in a range from about −300 volts (V) to about −800 V is applied to the substrate 11. The plasma then strikes the surface of the substrate 11 to clean the surface of the substrate 11. The plasma cleaning of the substrate 11 takes about 3 minutes (min) to about 10 min. The plasma cleaning process enhances the bond between the substrate 11 and the anti-corrosion layer 13.

The aluminum-copper alloy layer is vacuum sputtered on the plasma cleaned substrate 11. Vacuum sputtering of the aluminum-copper alloy layer is carried out in the vacuum chamber 21. The vacuum chamber 21 is heated to a temperature of about 100° C. to about 150° C. Ar is used as the sputtering gas and is fed into the vacuum chamber 21 at a flow rate of about 50 sccm to about 300 sccm. The aluminum-copper alloy targets 23 are supplied with electrical power of about 2 kw to about 8 kw. A negative bias voltage of about −50 V to about −200 V is applied to the substrate 11 and the duty cycle is from about 30% to about 80%. Deposition of the aluminum-copper alloy layer takes about 45 min to about 120 min.

Then Mn ions are implanted in the aluminum-copper alloy layer. An ion implantation device (not shown) is provided. The substrate 11 coated with the aluminum-copper alloy layer is positioned in the ion implantation device. Mn target in the ion implantation device will be evaporated and ionized to gaseous Mn ions. A high voltage electric field is applied, thus the gaseous Mn ions under high voltage electric field will become Mn ion beams with high energy, and the Mn ion beams are accelerated toward and implanted into the aluminum-copper alloy layer.

The conditions of the ion implanting are as following: the internal pressure of the ion implantation device is evacuated to about 1×10⁻⁴ Pa; the voltage of Mn ion source is about 30 thousand volts (kV) to about 100 kV; the Mn ion beam has an intensity of about 0.1 milliamperes (mA) to about 5 mA.

### EXAMPLES

Experimental examples of the present disclosure are described as followings.

### Example 1

The substrate 11 is made of aluminum alloy.

Plasma cleaning of the substrate 11 took place, wherein Ar was fed into the vacuum chamber 21 at a flow rate of about 380 sccm; a negative bias voltage of about −300 V was applied to the substrate 11; the plasma cleaning of the substrate 11 took about 9 min.

Sputtering for forming the aluminum-copper alloy layer took place, wherein Ar was fed into the vacuum chamber 21 at a flow rate of about 100 sccm; a power of about 2 kw was applied to the aluminum-copper alloy targets 23 and a negative bias voltage of −50 V was applied to the substrate 11; deposition of the aluminum-copper alloy took 100 min.

Ion implantation for forming the anti-corrosion layer 13 took place, wherein ion implantation device was evacuated to about 1×10⁻⁴ Pa; the voltage of Mn ion source was about 30 kV; the Mn ion beam had an intensity of about 0.1 mA. The density of the Mn ions implanted to the aluminum-copper alloy layer was from about 1×10¹⁶ ions/cm² to about 1×10¹⁸ ions/cm².

### Example 2

The substrate 11 is made of aluminum alloy.

Plasma cleaning of the substrate 11 took place, wherein Ar was fed into the vacuum chamber 21 at a flow rate of about 330 sccm; a negative bias voltage of about −480 V was applied to the substrate 11; the plasma cleaning of the substrate 11 took about 7 min.

Sputtering for forming the aluminum-copper alloy layer took place, wherein Ar was fed into the vacuum chamber 21 at a flow rate of about 200 sccm; a power of about 5 kw is applied to the aluminum-copper alloy targets 23 and a negative bias voltage of −100 V was applied to the substrate 11; deposition of the aluminum-copper alloy took 60 min.

Ion implantation for forming the anti-corrosion layer 13 took place, wherein ion implantation device was evacuated to about 1×10⁻⁴ Pa; the voltage of Mn ion source was about 60 kV; the Mn ion beam had an intensity of about 2 mA. The density of the Mn ions implanted to the aluminum-copper alloy layer was from about 1×10¹⁶ ions/cm² to about 1×10¹⁸ ions/cm².

### Example 3

The substrate 11 is made of aluminum alloy.

Plasma cleaning of the substrate 11 took place, wherein Ar was fed into the vacuum chamber 21 at a flow rate of about 360 sccm; a negative bias voltage of about −400 V was applied to the substrate 11; the plasma cleaning of the substrate 11 took about 6 min.

Sputtering for forming the aluminum-copper alloy layer took place, wherein Ar was fed into the vacuum chamber 21 at a flow rate of about 300 sccm; a power of about 8 kw is applied to the aluminum-copper alloy targets 23 and a negative bias voltage of −200 V was applied to the substrate 11; deposition of the aluminum-copper alloy took 45 min.

Ion implantation for forming the anti-corrosion layer 13 took place, wherein ion implantation device was evacuated to about 1×10⁻⁴ Pa; the voltage of Mn ion source was about 100 kV; the Mn ion beam had an intensity of about 5 mA. The density of the Mn ions implanted to the aluminum-copper alloy layer was from about 1×10¹⁶ ions/cm² to about 1×10¹⁸ ions/cm².

When the coated article 10 is in a corrosive environment, the anti-corrosion layer 13 can slow down galvanic corrosion of the substrate 11 due to the low potential difference between the anti-corrosion layer 13 and the substrate 11. Additionally, the anti-corrosion layer 13 is made homogeneously amorphous by implanting Mn ions and has dense structure, which can effectively slow penetration of outside corrosive mediums towards the substrate 11. Thus, the corrosion resistance of the coated article 10 is improved. The decorative layer 15 has stable properties and gives the coated article 10 a long lasting pleasing appearance.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a substrate, the substrate being made of aluminum or aluminum alloy;
an anti-corrosion layer formed on the substrate, the anti-corrosion layer being an aluminum-copper alloy layer implanted with manganese ions.

2. The coated article as claimed in claim 1, wherein the weight percentage of the manganese in the anti-corrosion layer is about 1% to about 30%.

3. The coated article as claimed in claim 1, wherein the anti-corrosion layer has a thickness of about 0.5 μm to about 6.0 μm.

4. The coated article as claimed in claim 1, wherein the aluminum-copper alloy layer is formed by magnetron sputtering.

6. A method for making a coated article, comprising:
providing a substrate, the substrate being made of aluminum or aluminum alloy;
magnetron sputtering a aluminum-copper alloy layer on the substrate; and
implanting manganese ions to the aluminum-copper alloy layer to form the anti-corrosion layer.

7. The method as claimed in claim 6, wherein magnetron sputtering the aluminum-copper alloy layer uses argon gas as the sputtering gas and the argon gas has a flow rate of about 50 sccm to about 300 sccm; magnetron sputtering the aluminum-copper alloy layer is carried out at a temperature of about 100° C. to about 150° C.; uses aluminum-copper alloy targets and the aluminum-copper alloy targets are supplied with a power of about 2 kw to about 8 kw; the weight percentage of copper in the aluminum-copper alloy targets is about 0.5% to about 25%; a negative bias voltage of about −50 V to about −200 V is applied to the substrate and the duty cycle is from about 30% to about 80%.

8. The method as claimed in claim 7, wherein magnetron sputtering the aluminum-copper alloy layer takes about 45 min to about 120 min.

9. The method as claimed in claim 6, wherein implanting the aluminum-copper alloy layer was done in a ion implantation device, the internal pressure of the ion implantation device was evacuated to about 1×10⁻⁴ Pa; the voltage of manganese ion source is about 30 kV to about 100 kV; the manganese ion beam has an intensity of about 0.1 mA to about 5 mA; the density of the manganese ions implanted to the aluminum-copper alloy layer is from about 1×10¹⁶ ions/cm² to about 1×10¹⁸ ions/cm².

10. The method as claimed in claim 6, wherein the method further includes plasma cleaning of substrate prior to magnetron sputtering the aluminum-copper alloy layer.
